(19) United States
(12) Patent Application Publication
(10) Pub. No.: US 2025/0233594 A1
(43) Pub. Date: Jul. 17, 2025

(54) Circuit and Method for Data Recovery

(71) Applicant: GOWIN Semiconductor Corporation, GuangZhou (CN)

(72) Inventors: Niu Li, GuangZhou (CN); Qi Zhou, GuangZhou (CN); Xiaozhi Lin, GuangZhou (CN); Qiming Wu, GuangZhou (CN)

(73) Assignee: GOWIN Semiconductor Corporation, GuangZhou, GD (CN)

(21) Appl. No.: 18/955,874

(22) Filed: Nov. 21, 2024

(30) Foreign Application Priority Data
Jan. 15, 2024 (CN) 2024100611808

(51) Int. Cl. H03L 7/091; H03L 7/081

(52) U.S. Cl. CPC H03L 7/091; H03L 7/0818

(57) ABSTRACT

A circuit and method for data recovery comprises clock generation, data reception, data oversampling, and data selection circuits; wherein, clock generation circuits are used to output data reception clock signals and data processing clock signals; data reception circuits are used to receive original transmission data from the data transmitter in accordance with the data reception clock signals, and transmit data based on its output; data oversampling circuits are used for multiple oversampling of at least one bit of transmission data corresponding to at least one data processing cycle according to the data processing clock signal and outputting corresponding parallel sample data; data selection circuits are used for transition detection on the corresponding parallel sample data for each data processing cycle and selecting sample data from the corresponding parallel sample data to output based on the transition detection results. The embodiments of the present application use a simple structure to implement data recovery, reducing layout area and circuit power consumption.

### PRIORITY

This application claims the benefit of priority of an earlier filed Chinese patent application Ser. No. 202410061180.8, having the same inventors, filed on Jan. 15, 2024 with China National Intellectual Property Administration of the People's Republic of China, entitled “A Circuit and Method for Data Recovery,” the disclosure of which is hereby incorporated by reference.

### FIELD

The present invention relates to circuit design technology, in particular a circuit and method for data recovery.

### BACKGROUND

High-speed IO data communication is one of the common requirements in circuit systems, with high-speed serial interfaces providing higher bandwidth, embedded clocks eliminating the need to transmit separate clocks, and avoiding the effects of multi-channel signal transmission delay skew. High-speed IO data communication involves both the data transmitter and the data receiver. The data receiver requires data recovery.

In related technologies, SerDes is often used for data recovery.

However, SerDes is complex and requires a large layout area and power consumption.

### SUMMARY

The present application discloses a data recovery circuit with a simple structure to implement data recovery, reducing layout area and power consumption.

Firstly, the present application discloses a circuit for data recovery, comprising clock generation, data reception, data oversampling, and data selection circuits;
wherein the clock generation circuit is used to output data reception clock signals and data processing clock signals;
wherein the data reception circuit is used to receive original transmission data from the data transmitter in accordance with the data reception clock signals, and outputs the transmission data based on the original transmission data;
wherein the data oversampling circuit is used for multiple oversampling of at least one bit of transmission data corresponding to at least one data processing cycle according to the data processing clock signal and outputting the parallel sample data corresponding to at least one data processing cycle;
wherein the data selection circuit is used for transition detection on the corresponding parallel sample data for each data processing cycle and selecting sample data from the corresponding parallel sample data to output based on the transition detection results.

Secondly, the present application discloses a data recovery method that is applied to any one of data recovery circuit described in the claims above, including:
wherein the clock generation circuit outputs data reception clock signals and data processing clock signals;
wherein the data reception circuit receives original transmission data from the data transmitter in accordance with the data reception clock signals, and outputs the transmission data based on the original transmission data;
wherein the data oversampling circuit performs multiple oversampling of at least one bit of transmission data corresponding to at least one data processing cycle according to the data processing clock signal and outputting the parallel sample data corresponding to at least one data processing cycle;
wherein the data selection circuit for each data processing cycle performs transition detection on the corresponding parallel sample data for each data processing cycle and selecting sample data from the corresponding parallel sample data to output based on the transition detection results.

Compared to related technologies, the present application comprises clock generation, data reception, data oversampling, and data selection circuits; wherein, the clock generation circuits are used to output data reception clock signals and data processing clock signals; the data reception circuits are used to receive original transmission data from the data transmitter in accordance with the data reception clock signals, and output data based on the original transmission data; the data oversampling circuits are used for multiple oversampling of at least one bit of transmission data corresponding to at least one data processing cycle according to the data processing clock signal and outputting parallel sample data corresponding to at least one data processing cycle according to the data processing clock signal and outputting the parallel sample data corresponding to at least one data processing cycle; the data selection circuits are used for transition detection on the corresponding parallel sample data for each data processing cycle and selecting sample data from the corresponding parallel sample data to output based on the transition detection results. The embodiments of the present application use a simple structure to implement data recovery, reducing layout area and circuit power consumption.

Additional features and benefits of the exemplary embodiment(s) of the present application will become apparent from the detailed description, figures, and claims set forth below. Additional benefits of the application can be realized and obtained through the solutions described in the detailed description and drawings.

Additional features and benefits of the exemplary embodiment(s) of the present application will become apparent from the detailed description, figures, and claims set forth below. Additional benefits of the application can be realized and obtained through the solutions described in the detailed description and drawings.

### BRIEF DESCRIPTION OF THE DRAWINGS

The exemplary embodiment(s) of the present invention will be understood more fully from the detailed description given below and from the accompanying drawings of various embodiments of the invention, which, however, should not be taken to limit the invention to the specific embodiments, but are for explanation and understanding only.

FIG. 1 is a structure diagram of one data recovery circuit for the embodiment of the present invention;

FIG. 2 is a structure diagram of another data recovery circuit for the embodiment of the present invention;

FIG. 3 is a relationship diagram of the phase processing of output delay circuits for the embodiment of the present invention;

FIG. 4 is a structure diagram of another data recovery circuit for the embodiment of the present invention;

FIG. 5 is a diagram of the serial and parallel conversion for the embodiment of the present invention;

FIG. 6 is a structure diagram of another data recovery circuit for the embodiment of the present invention;

FIG. 7 is a structure diagram of another data recovery circuit for the embodiment of the present invention;

FIG. 8 is a structure diagram of another data recovery circuit for the embodiment of the present invention;

FIG. 9 is a structure diagram of another data recovery circuit for the embodiment of the present invention;

FIG. 10 is a diagram of the detection of phase voters for the embodiment of the present invention;

FIG. 11 is a diagram of a phase selection for the embodiment of the present invention;

FIG. 12 is a structure diagram of another data recovery circuit for the embodiment of the present invention;

FIG. 13 is a diagram of one frequency control circuit controlling data output circuits for the embodiment of the present invention;

FIG. 14 is a diagram of another frequency control circuit controlling data output circuits for the embodiment of the present invention;

FIG. 15 is a diagram of the temperature sensing control circuit controlling output delay circuits for the embodiment of the present invention;

FIG. 16 is a structure diagram of another data recovery circuit for the embodiment of the present invention;

FIG. 17 is a flow chart of a data recovery method for the embodiment of the present invention.

### DETAILED DESCRIPTION

Embodiments of the present invention disclose a circuitry, method, computer storage medium and terminal for deskew processing.

The present application describes multiple embodiments, but the description is exemplary and not limiting, and it will be obvious to those of ordinary skill in the art that there can be more embodiments within the scope of the embodiments described in the present application. Although many possible combinations of features are illustrated in the drawings and discussed in the detailed description, many other combinations of the disclosed features are possible. Unless specifically limited, any feature or element of any embodiment may be combined with any other feature or element of any other embodiment, or may substitute for any other feature or element of any other embodiment.

The present application includes and contemplates combinations with features and elements known to those of ordinary skill in the art. The embodiments, features, and elements that have been disclosed in the present application may also be combined with any conventional features or elements to form a unique invention as limited by the claims. Any feature or element of any embodiment may also be combined with features or elements from other invention embodiments to form another unique invention embodiment limited by the claims. Accordingly, it should be understood that any of the features illustrated and/or discussed in this application may be realized individually or in any proper combination. Accordingly, In addition to the limitations imposed in accordance with the appended claims and their equivalents, no other limitations are placed on the embodiments. In addition, various modifications and changes may be made within the protection scope of the appended claims.

Furthermore, in describing representative embodiments, the detailed description may have presented the method and/or process as a particular sequence of steps. However, to the extent that the method or process does not depend on a particular sequence of steps described herein, the method or process should not be limited to the particular sequence of steps described. As those of ordinary skill in the art will understand, other sequence of steps is possible. Thus, the particular sequence of steps set forth in the detailed description should not be construed as a limitation of the claims. Furthermore, the claims directed to the method and/or process should not be limited to the steps of performing them in the order in which they are written, and it can be readily understood by those of ordinary skill in the art that these orders can be varied and still remain within the spirit and scope of the embodiments of the present application.

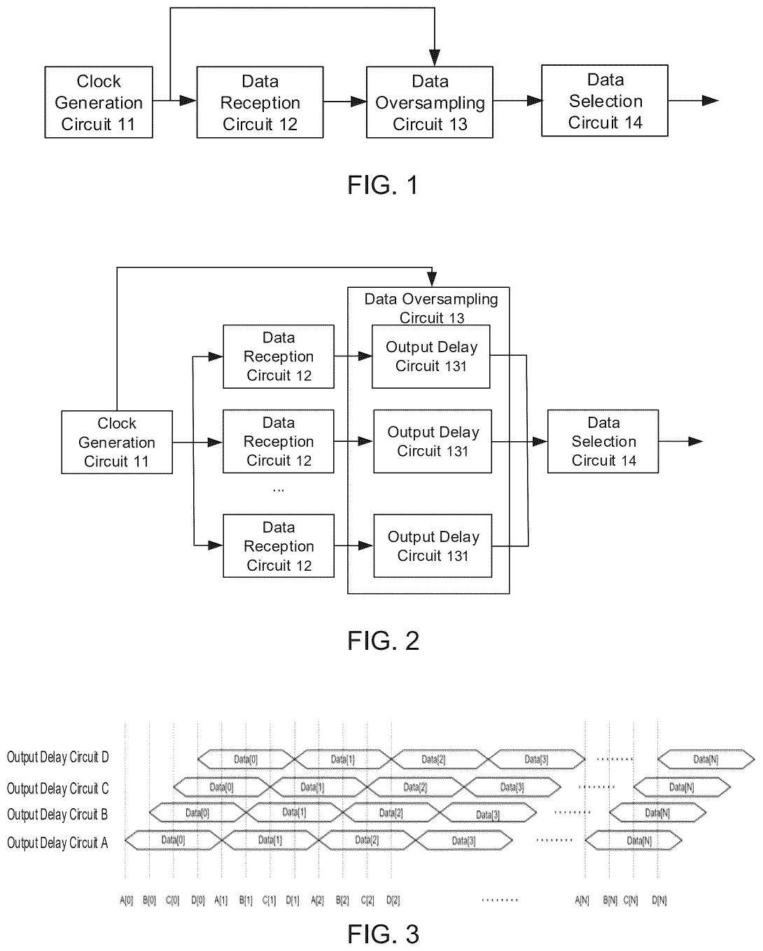

The embodiments of the present invention disclose a circuit for data recovery shown in FIG. 1, comprising clock generation circuit 11, data reception circuit 12, data oversampling circuit 13, and data selection circuit 14;
wherein the clock generation circuit 11 is used to output data reception clock signals and data processing clock signals;
wherein the data reception circuit 12 is used to receive original transmission data from the data transmitter in accordance with the data reception clock signals, and outputs the transmission data based on the original transmission data;
wherein the data oversampling circuit 13 is used for multiple oversampling of at least one bit of transmission data corresponding to at least one data processing cycle according to the data processing clock signal and outputting the parallel sample data corresponding to at least one data processing cycle;
wherein the data selection circuit 14 for each data processing cycle performs transition detection on the corresponding parallel sample data for each data processing cycle and selecting sample data from the corresponding parallel sample data to output based on the transition detection results.

To implement oversampling, the frequency of data processing clock signal is higher than that of data reception clock signal.

Data recovery does not limit the multiple of oversampling, but according to the sampling principle, at least 2 times oversampling is required to recover the signal, and in practice a multiple of 4 times or more is often used. High-multiple sampling can improve performance but also result in larger layout area and power consumption, requiring a trade-off based on actual application requirements.

The data recovery circuit in the embodiments of the present application use a simple structure to implement data recovery, reducing layout area and circuit power consumption.

In an exemplary embodiment, as shown in FIG. 2, the data oversampling circuit 13 includes M output delay circuits 131 set in parallel and corresponding one-to-one to M preset first interpolation phases; the data processing clock signal includes the first data processing sub-clock signal;

The i^{th} output delay circuit 131 for one-bit transmission data received from each data processing cycle, performs interpolation phase process of the transmission data according to the i^{th} first interpolation phase corresponding to the i^{th} output delay circuit according to the first data processing sub-clock signal. And use the transmission data obtained by the interpolation process as the sampling data of the transmission data received in this data processing cycle in the i^{th} first interpolation phase, and output it. i is each integer value from 1 to M, including both 1 and M, where M is an integer greater than 1.

One output delay circuit outputs 1-bit sample data. When the data oversampling circuit includes M output delay circuits, M-bit parallel sample data will be output.

For example, when the data oversampling circuit 13 includes multiple output delay circuit 131, the data reception circuit 12 can also correspond one-to-one to the multiple output delay circuit 131.

For example, the output delay circuits can provide high-precision delays. Assuming that the channel number of the output delay circuit is 4, the output delay circuits are A, B, C, and D. For a signal with a period of T, the delays of 0*T, 0.25*T, 0.5*T, and 0.75*T are provided through the 4 circuits ABCD. The phase processing relationship of the 4 output delay circuits is shown in FIG. 3, where each data, i.e., Data[0], Data[1] . . . Data[N], is sampled 4 times respectively to get the 4 times oversampling information.

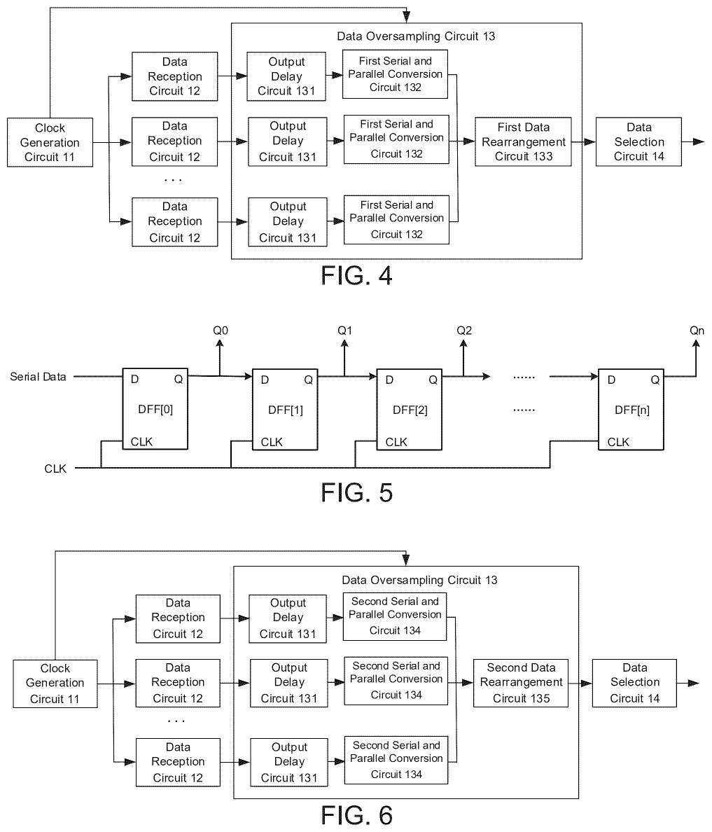

In an exemplary embodiment, as shown in FIG. 4, the data oversampling circuit 13 further includes M first serial and parallel conversion circuits 132 corresponding one-to-one to M output delay circuits 131; the first data rearrangement circuit 133 connected to M first serial and parallel conversion circuits 132.

The i^{th} first serial and parallel conversion circuit 132 for serial and parallel conversion of the first preset number of bits on the serial sample data output by the corresponding i^{th} output delay circuit in the i^{th} interpolation phase, outputs the first parallel sample data in the i^{th} first interpolation phase; wherein the serial sample data is obtained by interpolating the multiple-bit transmission data received by the i^{th} output delay circuit over multiple data transmission cycles according to the i^{th} interpolation phase;

The first data rearrangement circuit 132 is used to arrange the positions of the first target parallel sample data formed from the first parallel sample data output by the M first serial-to-parallel conversion circuit 132 according to the timing. And the adjusted first target parallel sample data is as the parallel bit sample data corresponding to at least one data processing cycle.

Besides phase interpolation, output delay circuit can further increase the bit width and reduce the frequency, so the serial and parallel conversion circuits are increased. And due to the increase of the serial and parallel conversion circuits, all the timing of the parallel sample data output by the serial and parallel conversion circuits is intertwined, so it is necessary to increase data rearrangement circuits in order to organize the bit data in accordance with the timing, so that the sample data of different interpolation phases in the same data processing cycle are clustered together, facilitating edge detection later on.

For example, serial and parallel conversion can be implemented in the form of Serial In Parallel Out (SIPO), which converts serial data to parallel data at the common ratios of 1:4, 1:8, 1:16 and so on through general-purpose input/output (GPIO) logic resources. The diagram of SIPO serial and parallel conversion is shown in FIG. 5. Assuming that D flip-flops (DFF) include DFF[0], DFF[1], DFF[2] . . . DFF[n], input serial data, DFF[0] outputs the first bit of the serial data, Q₀, based on the first signal transmission cycle of the clock signal (clk). DFF[1] outputs the second bit of the serial data, Q₁, based on the clock signal (clk) for the second signal transmission cycle. The DFF[2] outputs the third bit of serial data, Q₂, based on the third signal transmission cycle of the clock signal (clk) . . . . DFF[n] outputs the n^{th} bit of serial data, Qₙ, based on the n^{th} signal transmission cycle of the clock signal (clk).

Serial and parallel conversion circuit specifically can be IDES module. In order to support the improvement of the data rate, IDES module can provide 1:16 bit width conversion, which can ensure that 64-bit data is sampled in each parallel clock cycle. After the subsequent processing of the oversampling module, 16-bit valid data is obtained. At low data rates, the number of output delay modules (IODELAY) and the ratio of IDES can be reduced so that the parallel data bit width can be reduced to as low as 4-bit, and select 1-bit valid data. With such a method, the whole range of applications with low to medium data rates can be covered. Of course such a method is also applicable to high data rate applications, but it requires that the physical bit width of the IOs be increased by design, which increases the layout area and power consumption of the GPIOs and requires careful consideration.

In an exemplary embodiment, as shown in FIG. 6, the data oversampling circuit 13 includes M second serial and parallel conversion circuits 134 corresponding one-to-one to M output delay circuits, and second rearrangement circuits 135. Each of the second serial and parallel conversion circuits 134 corresponds to N second interpolation phases. The data processing clock signal further includes the second data processing sub-clock signal.

The i^{th} second serial-to-parallel conversion circuit 134 for the j^{th} second interpolation phase, according to the second data processing of the sub-clock signal, performs the j^{th} second interpolation phase processing and the serial-to-parallel conversion processing of the second preset number of bits on the serial sample data of the corresponding i^{th} output delay circuit 131 in the i^{th} interpolation phase, and outputs the i^{th} first interpolation phase and the second parallel sample data in the j^{th} second interpolation phase. j is each integer value from 1 to N, including both 1 and N, where N is an integer greater than 1;

The second data rearrangement circuit 135 is used to arrange the positions of the N second target parallel sample data formed from the second parallel sample data output by the M second serial-to-parallel conversion circuits 134 according to the timing. And the adjusted second target parallel sample data is as the parallel bit sample data corresponding to at least one data processing cycle.

For the data recovery circuit in the embodiment of the present application, the second serial and parallel conversion circuit not only the performs the serial and parallel conversion processing, but also the phase interpolation processing, thus further reducing the frequency.

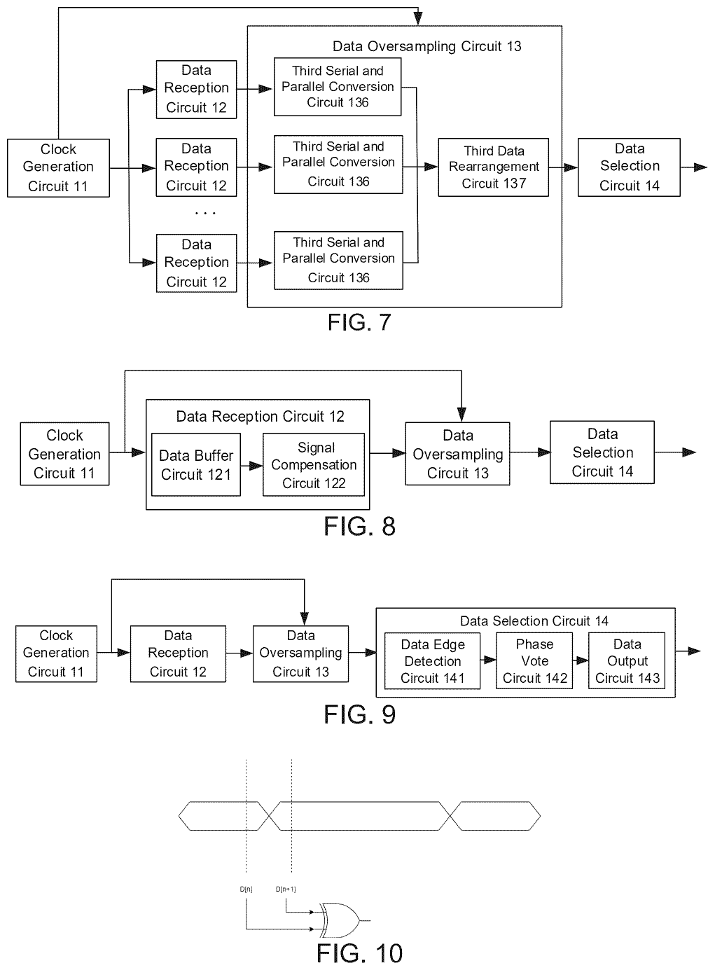

In an exemplary embodiment, as shown in FIG. 7, the data oversampling circuit 13 includes third serial and parallel conversion circuits 136 and third rearrangement circuits 137; The third serial and parallel conversion circuits 136 correspond to the S third interpolation phases. The data processing clock signal further includes the third data processing sub-clock signal.

The third serial and parallel conversion circuit 136 for one-bit transmission data received from each data processing cycle, performs the k^{th} third interpolation phase processing of the transmission data according to the third data processing sub-clock signal. And the interpolated transmission data is as the sample data of the transmission data received over this data processing cycle in the k^{th} third interpolation phase;

The third serial and parallel conversion circuit 136 for the serial and parallel conversion of the third preset number of bits on the serial sample data output in the kl interpolation phase, outputs the third parallel sample data in the k^{th} third interpolation phase; wherein k is each integer value from 1 to S, including both 1 and S, where S is an integer greater than 1;

The third data rearrangement circuit 137 is used to arrange the positions of the third target parallel sample data formed from the third parallel sample data in the S third interpolation phases according to the timing. And the adjusted third target parallel sample data is as the parallel bit sample data corresponding to at least one data processing cycle.

For the data recovery circuit in the embodiment of the present application, the third serial and parallel conversion circuit is used to perform the serial and parallel conversion processing and the phase interpolation processing, thus increasing the bit width and reducing the frequency.

In an exemplary embodiment, as shown in FIG. 8, the data reception circuit 12 includes data buffer circuits 121 and signal compensation circuits 122;
wherein the data reception circuit receives original transmission data from the data transmitter in accordance with the data reception clock signals, and outputs the transmission data based on the original transmission data, comprising;
wherein the data buffer circuit 121 is used to receive the original transmission data from the data transmitter and output it;
wherein the signal compensation circuit 122 is used to performing signal compensation processing on the original transmission data to obtain the transmission data and output it.

In an exemplary embodiment, as shown in FIG. 9, the data selection circuit 14 includes data edge detection circuit 141, phase vote circuit 142, and data output circuit 143;
wherein the data edge detection circuit 141 for each data processing cycle is used to detect whether or not an edge transition is generated between each two adjacent sample data in the parallel sample data corresponding to the current data processing cycle by means of an exclusive-OR (XOR) gate, and to determine the edge transition position in the current data processing cycle;
wherein the phase vote circuit 142 is used to determine the interpolation phase of the current data processing cycle according to the edge transition position detected by the current data processing cycle;
wherein the data output circuit 143 is used to output the sample data corresponding to the determined interpolation phase.

For example, the data edge detection circuit can specifically use a phase detector for edge transition detection, the diagram of detection with phase detector is shown in FIG. 10, which detects whether or not an edge transition is generated between each two adjacent sample points by means of an XOR gate. If the values for 2 sample points are the same, there is no edge transition and XOR gate outputs 0. If the values for 2 sample points are different, there is edge transition and XOR gate outputs 1.

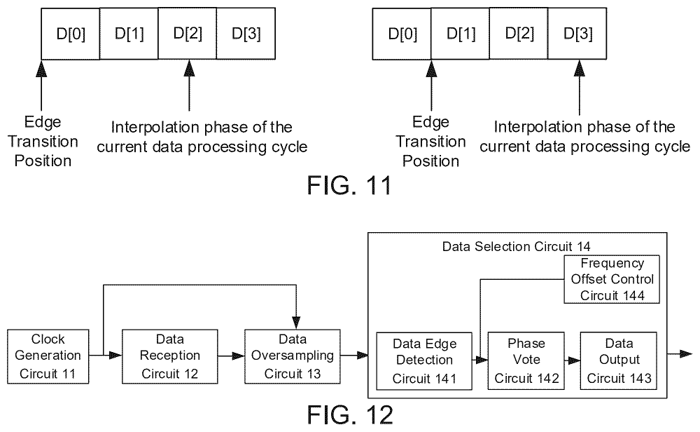

For example, taking 4 times oversampling as an example, the phase vote circuit 142 determines the interpolation phase of the current data processing cycle based on the edge transition position detected by the current data processing cycle, as shown in FIG. 11. If the edge transition occurs on the left side of D[0], then D[2] is the interpolation phase determined by the phase vote circuit 142, i.e. the sample point (+2) of the optimal phase is more likely to be in the center of the signal eye diagram. Similarly, if the edge transition occurs to the left of D[1], then D[3] is the interpolation phase determined by the phase vote circuit 142, which is the sample point of the optimal phase.

In an exemplary embodiment, as shown in FIG. 12, the data selection circuit further includes frequency offset control circuits 144.

In an exemplary embodiment, the frequency offset control circuit 144 is used to monitor the edge transition position in each data processing cycle, and whenever the edge transition position of the target data processing cycle is monitored in accordance with the preset conditions, send data output control instructions corresponding to the preset conditions to the data output circuit;

The data output circuit 143 is used to output corresponding to the data output control instructions in the target data processing cycle.

In an exemplary embodiment, the edge transition position of the target data processing cycle is monitored in accordance with the preset conditions by the frequency offset control circuit, send data output control instructions corresponding to the preset condition to the data output circuit, including:
wherein whenever the edge transition position of the target data processing cycle is monitored between the sample data of the penultimate and last interpolation phases by the frequency offset control circuit 144, send the first data output control instructions for outputting 1-bit more sample data to the data output circuit 143.

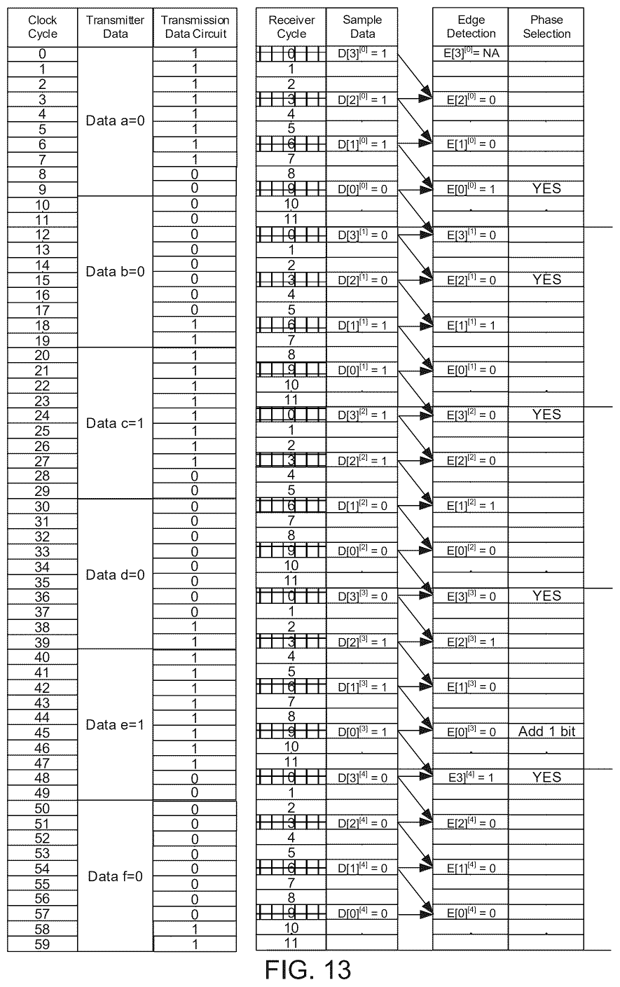

For example, the diagram of the frequency control circuit controlling data output circuit is shown in FIG. 13, wherein the transmitter (Tx) clock data rate is assumed to be 10, the receiver (Rx) local parallel clock cycle is 12, the high-speed clock cycle is 3 (4× oversampling), D[m]^{[n]} is the m^{th} sample data for the n^{th} clock cycle, and E[m]^{[n]} is the n^{th} clock cycle or the m^{th} edge detection value. As shown in FIG. 13, in the fourth cycle, the selected data transitions directly from D[3]^{[3]} to D[0]^{[4]}, skipping over 1-bit data, which need to be added. Therefore, the edge transition position of the target data processing cycle is monitored between the sample data of the penultimate and last interpolation phases by the frequency offset control circuit 144, send the first data output control instructions for outputting 1-bit more sample data to the data output circuit 143, data output circuit 143 selects D[0]^{[3]} as the 1-bit more sample data according to the phase relationship.

In an exemplary embodiment, the edge transition position of the target data processing cycle is monitored in accordance with the preset conditions by the frequency offset control circuit, send data output control instructions corresponding to the preset condition to the data output circuit, including:
wherein whenever the edge transition position of the target receiving cycle is monitored between the sample data of the first and second interpolation phases by the frequency offset control circuit 144, send the second data output control instructions for outputting 1-bit less sample data to the data output circuit.

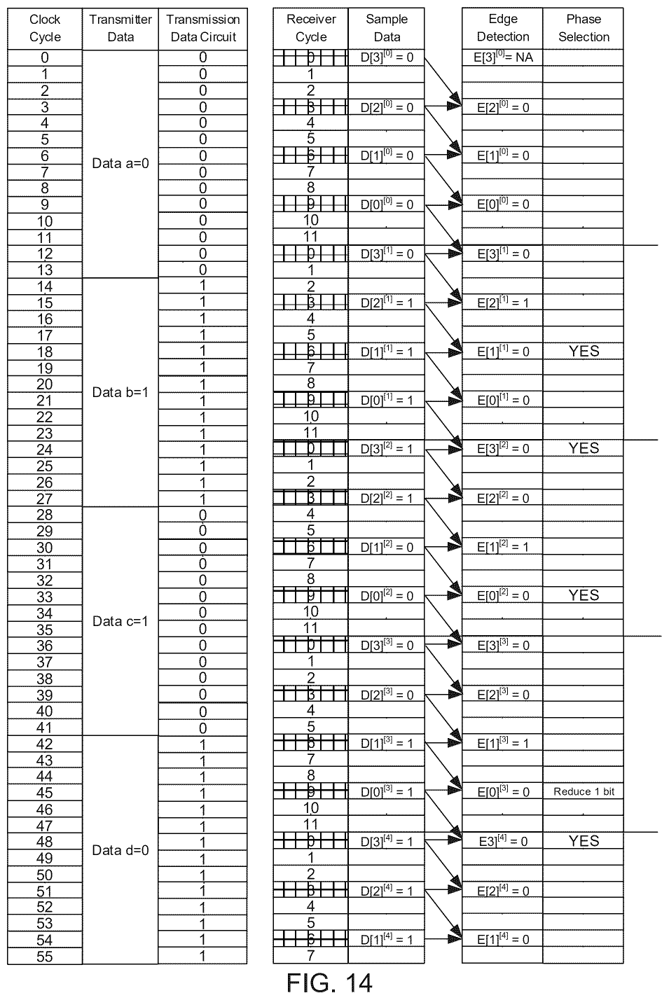

For example, the diagram of the frequency control circuit controlling data output circuit is shown in FIG. 14, wherein the transmitter (Tx) clock data rate is still assumed to be 10, the receiver (Rx) local parallel clock cycle is 12, the high-speed clock cycle is 3 (4× oversampling), D[m]^{[n]} is the m^{th} sample data for the n^{th} clock cycle, and E[m]^{[n]} is the n^{th} clock cycle or the m^{th} edge detection value. As shown in FIG. 14, in the fourth cycle, the selected data transitions directly from D[0]^{[3]} to D[3]^{[4]}, which need to be skipped. Therefore, the edge transition position of the target reception processing cycle is monitored between the sample data of the first and second interpolation phases by the frequency offset control circuit 144, send the first data output control instructions for outputting 1-bit less sample data to the data output circuit 143, data output circuit 143 selects D[0]^{[3]} as the 1-bit less sample data according to the phase relationship.

It should be noted that the number of digital circuit output bits is certain, therefore it necessary to set the maximum possible number of output bits, and identify the valid flag bits to indicate the actual output data, assuming that the data selection circuit is 4 sample data to select 1 sample data, then the number of output bits designed for the data output circuit is 2 (more than 1 bit is reserved for the purpose of needing to output more than 1-bit data in some clock cycles). If the data selection circuit is 32 sample data to select 8 sample data, the number of output bits designed for the data output circuit is 9.

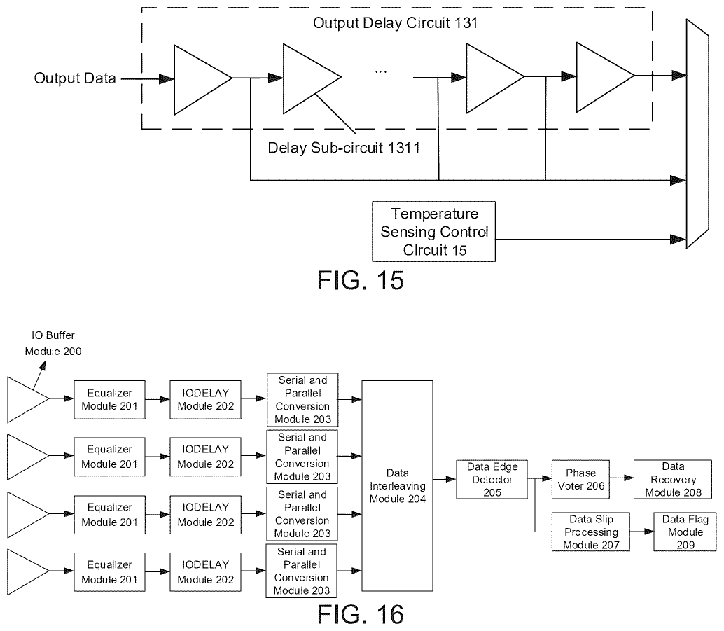

In an exemplary embodiment, as shown in FIG. 15, the data recovery circuit further includes temperature sensing control circuit 15. Each output delay circuit includes multi-stage delay sub-circuit 1311;

For each of the output delay circuits 131, the temperature sensing control circuit is connected to the multi-stage delay sub-circuit 1311 of the output delay circuit through the multiplexer corresponding one-to-one to the multi-stage delay sub-circuit 1311, wherein each selector switch is used to control the corresponding delay sub-circuit 1311 of the corresponding output delay circuit 131;

The temperature sensing control circuit 15 is used to obtain the changes in external temperature and determine the delay sub-circuit 1311 to be turned on or off based on the acquired temperature changes, and send an “on” instruction to the delay sub-circuit 1311 determined to be turned on, and send an “off” instruction to the delay sub-circuit 1311 determined to be turned off.

The delay circuit is cascaded with multi-stage buffers to compose an output delay circuit, and different delay times can be obtained by selecting the number of different delay sub-circuits in series through the MUX in FIG. 15. Complementary Metal Oxide Semiconductor (CMOS) circuits are easily affected by external environment. Through the sensor senses the change of external conditions to compensate for the influence of the external environment on the delay accuracy, the coefficients of each factor can be calibrated through the circuit simulation and the actual circuit measurements to obtain the corresponding polynomial coefficients. The hardware circuit implements the smooth control algorithm, which increases or decreases the number of cascades gradually instead of a big step change. Through this mechanism to control IODELAY to ensure the stability of the delay, effectively avoiding the influence of the external environment on the delay time.

The embodiment of the present application discloses a data recovery circuit, as shown in FIG. 16, including: IO buffer module 200, equalizer module 201, IODELAY module 202, serial and parallel conversion module 203, data interleaving module 204, data edge detector 205, phase vote 206, data slip processing module 207, data recovery module 208, data flag module 209, and temperature voltage and process compensation circuit 210;
wherein, the IO buffer module 200 is used to receive external analog voltage signals such as LVCOMS, LVDS, etc., to the inside of the chip;
wherein, the equalizer module 201 can compensate the attenuation for PCB traces of external packages, connection cables, and so forth, specifically optimized for low-speed applications in field-programmable gate arrays (FPGA) to reduce power consumption;
wherein, the IODELAY module 202 is for high-precision delay, thus enhancing high-precision phase interpolation;
wherein, the serial and parallel conversion module 203 is for serial and parallel conversion functions via shift registers and corresponding control timings, such as 1:8, 1:16. This is to reduce the parallel speed since the digital clock domain cannot be so fast;
Data interweaving module 204 is used to recombine data converted from 203 in a chronological order;
Data edge detector 205 is used to detect data edge transitions;
Phase voter 206 is used to vote the optimal phases via phase transition signals;
Data slip processing module 207 is used to process the bit slip generated by the skew of the remote data and the local clock frequency resulting in data spanning more than a single cycle range;
Data recovery module 208 is used to output the recovered data;
Data flag module 209 is used to identify the valid output data;

Temperature voltage and process compensation circuit 210 is used to protect IODELAY from changes in environmental conditions.

The embodiment of the present application discloses a data recovery circuit applicable to FPGAs and ASICs (Application Specific Integrated Circuit). The applicable scenarios can be widely used for reception of high-speed serial data. For example, USB 2.0, Serial Gigabit Media Independent Interface (SGMII), Passive Optical Network (PON) optical line terminal (OLT), High Definition Multimedia Interface (HDMI), and DisplayPort, etc. For the FPGA development platform, the IP module mentioned in the present invention is called, the corresponding protocol is adapted, and the final generated bitstream file is loaded into the FPGA chip. For ASIC solutions, first of all, it is necessary to design analog circuits (mainly analog front-end circuits, IOB buffer, equalizer, delay module, etc.) and digital circuits (oversampling algorithms) according to the architecture, and the corresponding application layer protocol algorithms. Then, through the process of synthesis, layout, routing, etc., the corresponding GDS file is generated and sent to the factory for chip package testing. The user needs to write the appropriate amount of firmware based on the circuit design.

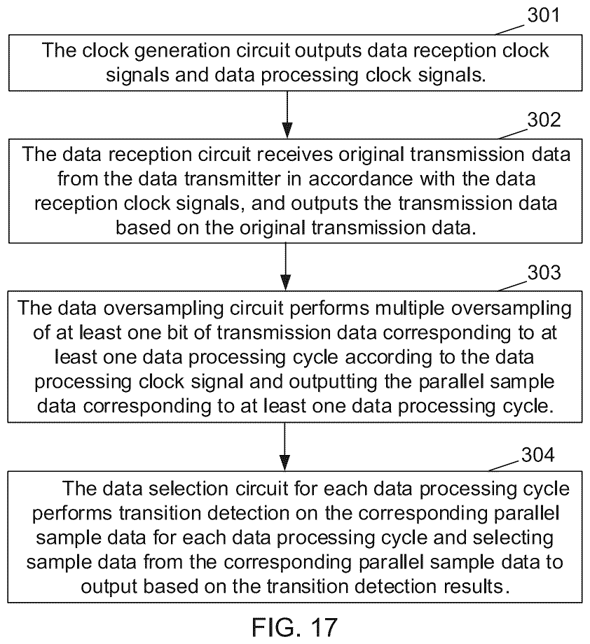

The present application discloses a data recovery method that is applied to any one embodiment data recovery circuit described above, as shown in FIG. 17, including:
At block 301, the clock generation circuit outputs data reception clock signals and data processing clock signals;
At block 302, the data reception circuit receives original transmission data from the data transmitter in accordance with the data reception clock signals, and outputs the transmission data based on the original transmission data;
At block 303, the data oversampling circuit performs multiple oversampling of at least one bit of transmission data corresponding to at least one data processing cycle according to the data processing clock signal and outputting the parallel sample data corresponding to at least one data processing cycle;
At block 304, the data selection circuit for each data processing cycle performs transition detection on the corresponding parallel sample data for each data processing cycle and selecting sample data from the corresponding parallel sample data to output based on the transition detection results.

The data recovery method in the embodiments of the present application use a simple structure to implement data recovery, reducing layout area and circuit power consumption.

In an exemplary embodiment, the data oversampling circuit includes M output delay circuits set in parallel and corresponding one-to-one to M preset first interpolation phases; the data processing clock signal includes the first data processing sub-clock signal.

In an exemplary embodiment, the method further includes:

The i^{th} output delay circuit for one-bit transmission data received from each data processing cycle, performs interpolation phase process of the transmission data according to the i^{th} first interpolation phase corresponding to the i^{th} output delay circuit according to the first data processing sub-clock signal. And use the transmission data obtained by the interpolation process as the sampling data of the transmission data received in this data processing cycle in the i^{th} first interpolation phase, and output it. i is each integer value from 1 to M, including both 1 and M, where M is an integer greater than 1.

In an exemplary embodiment, the data oversampling circuit further includes first data rearrangement circuit and M first serial and parallel conversion circuits corresponding one-to-one to M output delay circuits; the first data rearrangement circuit is connected to M first serial and parallel conversion circuits.

In an exemplary embodiment, the method further includes:
Firstly, the i^{th} first serial and parallel conversion circuit for serial and parallel conversion of the first preset number of bits on the serial sample data output by the corresponding i^{th} output delay circuit in the i^{th} interpolation phase, outputs the first parallel sample data in the i^{th} first interpolation phase; wherein the serial sample data is obtained by interpolating the multiple-bit transmission data received by the i^{th} output delay circuit over multiple data transmission cycles according to the i^{th} interpolation phase;
Secondly, the first data rearrangement circuit is to arrange the positions of the first target parallel sample data formed from the first parallel sample data output by the M first serial and parallel conversion circuits according to the timing. And the adjusted first target parallel sample data is as the parallel bit sample data corresponding to at least one data processing cycle.

In an exemplary embodiment, the first data rearrangement circuit is used to arrange the positions of the first target parallel sample data formed from the first parallel sample data output by the M first serial and parallel conversion circuits according to the timing. And the adjusted first target parallel sample data is as the parallel bit sample data corresponding to at least one data processing cycle.

In an exemplary embodiment, the method further includes:
Firstly, the i^{th} second serial and parallel conversion circuit for the j^{th} second interpolation phase, according to the second data processing of the sub-clock signal, performs the j^{th} second interpolation phase processing and the serial and parallel conversion processing of the second preset number of bits on the serial sample data of the corresponding i^{th} output delay circuit in the i^{th} interpolation phase, and outputs the i^{th} first interpolation phase and the second parallel sample data in the j^{th} second interpolation phase. j is each integer value from 1 to N, including both 1 and N, where N is an integer greater than 1;
Secondly, the second data rearrangement circuit arranges the positions of the N second target parallel sample data formed from the second parallel sample data output by the M second serial and parallel conversion circuits according to the timing. And the adjusted second target parallel sample data is as the parallel bit sample data corresponding to at least one data processing cycle.

In an exemplary embodiment, the data oversampling circuit includes third serial and parallel circuits and third rearrangement circuits. The third serial and parallel conversion circuits correspond to the S third interpolation phases. The data processing clock signal further includes the third data processing sub-clock signal.

In an exemplary embodiment, the method further includes:
Firstly, the third serial and parallel conversion circuit for one-bit transmission data received from each data processing cycle, performs the k^{th} third interpolation phase processing of the transmission data according to the third data processing sub-clock signal. And the interpolated transmission data is as the sample data of the transmission data received over this data processing cycle in the k^{th} third interpolation phase;
Secondly, the third serial and parallel conversion circuit performs the serial and parallel conversion of the third preset number of bits on the serial sample data output in the k^{th} interpolation phase, and outputs the third parallel sample data in the k^{th} third interpolation phase; wherein k is each integer value from 1 to S, including both 1 and S, where S is an integer greater than 1;
Finally, the third data rearrangement circuit arranges the positions of the third target parallel sample data formed from the third parallel sample data in the S third interpolation phases according to the timing. And the adjusted third target parallel sample data is as the parallel bit sample data corresponding to at least one data processing cycle.

In an exemplary embodiment, the data reception circuit includes data buffer circuits and signal compensation circuits.

In an exemplary embodiment, the data reception circuit receives original transmission data from the data transmitter in accordance with the data reception clock signals, and outputs the transmission data based on the original transmission data, comprising:
Firstly, the data buffer circuit receives the original transmission data from the data transmitter and outputs it;
Secondly, the signal compensation circuits perform signal compensation processing on the original transmission data to obtain the transmission data and outputs it.

In an exemplary embodiment, the data selection circuit includes data edge detection circuit, phase vote circuit, and data output circuit.

In an exemplary embodiment, the method further includes:
Firstly, the data edge detection circuit for each data processing cycle detects whether or not an edge transition is generated between each two adjacent sample data in the parallel sample data corresponding to the current data processing cycle by means of an exclusive-OR (XOR) gate and determines the edge transition position in the current data processing cycle;
Secondly, the phase vote circuit determines the interpolation phase of the current data processing cycle according to the edge transition position detected by the current data processing cycle;
Finally, the data output circuit outputs the sample data corresponding to the determined interpolation phase.

In an exemplary embodiment, the data selection circuit further includes frequency offset control circuits.

In an exemplary embodiment, the method further includes:
Firstly, the frequency offset control circuit monitors the edge transition position in each data processing cycle, and whenever the edge transition position of the target data processing cycle is monitored in accordance with the preset conditions, send data output control instructions corresponding to the preset conditions to the data output circuit;
Secondly, the data output circuit outputs corresponding to the data output control instructions in the target data processing cycle.

In an exemplary embodiment, the edge transition position of the target data processing cycle is monitored in accordance with the preset conditions by the frequency offset control circuit, send data output control instructions corresponding to the preset condition to the data output circuit, including:

Wherein whenever the edge transition position of the target data processing cycle is monitored between the sample data of the penultimate interpolation phase and the sample data of the last interpolation phase by the frequency offset control circuit, send the first data output control instructions of the multiple output 1-bit sample data to the data output circuit.

In an exemplary embodiment, the edge transition position of the target data processing cycle is monitored in accordance with the preset conditions by the frequency offset control circuit, send data output control instructions corresponding to the preset condition to the data output circuit, including:
wherein whenever the edge transition position of the target receiving cycle is monitored between the sample data of the first and second interpolation phases by the frequency offset control circuit, send the second data output control instructions for outputting 1-bit less sample data to the data output circuit.

In an exemplary embodiment, the data recovery circuit further includes temperature sensing control circuit. Each output delay circuit includes multi-stage delay sub-circuit;

For each of the output delay circuits, the temperature sensing control circuit is connected to the multi-stage delay sub-circuit of the output delay circuit through the multiplexer corresponding one-to-one to the multi-stage delay sub-circuit, wherein each selector switch is used to control the corresponding delay sub-circuit of the corresponding output delay circuit.

In an exemplary embodiment, the method further includes:

The temperature sensing control circuit obtains the changes in external temperature and determines the delay sub-circuit to be turned on or off based on the acquired temperature changes, and sends an “on” instruction to the delay sub-circuit determined to be turned on, and sends an “off” instruction to the delay sub-circuit determined to be turned off.

Those of ordinary skills in the art will recognize that some or all of the steps, systems, and functional modules/units in the devices disclosed above may be implemented as software, firmware, hardware, and suitable combinations thereof. In hardware implementations, the division between functional modules/units referred to in the above description does not necessarily correspond to the division of physical components; for example, a physical component may have more than one function, or a function/step may be cooperatively performed by several physical components. Some or all of the components may be implemented as software executed by a processor, such as a digital signal processor or microprocessor, or as hardware, or as an IC, such as ASIC. Such software may be distributed on computer-readable media, including computer storage media (or non-volatile media) and communication media (or non-volatile media). Those of ordinary skills in the art will recognize that the term computer storage medium includes volatile, non-volatile, removable, and non-removable media implemented in any method or technique for storing information, such as computer-readable instructions, data structures, program modules or other data. The computer storage medium includes, but not limited to, RAM, Read Only Memory (ROM), electrically erasable programmable read-only memory (“EEPROM”), flash memory or other memory technology, compact disc read-only memory (CD-ROM), Digital Versatile Disc (DVD), or other optical disc storage, magnetic disk, magnetic tape, magnetic disk storage, or any other media capable of storing desired information and accessible by a computer. In addition, those of ordinary skills in the art will recognize that the communication medium typically contains computer-readable instructions, data structures, program modules, or other data in a modulated data signal such as a carrier wave or other transmission mechanism, and any information delivery medium.

What is claimed is:

1. A circuit for data recovery applied to the data receiver, comprising clock generation, data reception, data oversampling, and data selection circuits;
wherein the clock generation circuit is used to output data reception clock signals and data processing clock signals;
wherein the data reception circuit is used to receive original transmission data from the data transmitter in accordance with the data reception clock signals, and outputs the transmission data based on the original transmission data;
wherein the data oversampling circuit is used for multiple oversampling of at least one bit of transmission data corresponding to at least one data processing cycle according to the data processing clock signal and outputting the parallel sample data corresponding to at least one data processing cycle;
wherein the data selection circuit for each data processing cycle is used for transition detection on the corresponding parallel sample data for each data processing cycle and selecting sample data from the corresponding parallel sample data to output based on the transition detection results.

2. The device of claim 1, wherein the data oversampling circuit includes M output delay circuits set in parallel and corresponding one-to-one to M preset first interpolation phases; the data processing clock signal includes the first data processing sub-clock signal;
the i^{th} output delay circuit for one-bit transmission data received from each data processing cycle, performs interpolation phase process of the transmission data according to the i^{th} first interpolation phase corresponding to the i^{th} output delay circuit according to the first data processing sub-clock signal. And use the transmission data obtained by the interpolation process as the sampling data of the transmission data received in this data processing cycle in the i^{th} first interpolation phase, and output it. i is each integer value from 1 to M, including both 1 and M, where M is an integer greater than 1.

3. The device of claim 2, wherein the data oversampling circuit further includes first data rearrangement circuits and M first serial and parallel conversion circuits corresponding one-to-one to M output delay circuits; the M first serial and parallel conversion circuit is connected to the first data rearrangement circuit;
the i^{th} first serial and parallel conversion circuit for serial and parallel conversion of the first preset number of bits on the serial sample data output by the corresponding i^{th} output delay circuit in the i^{th} interpolation phase, outputs the first parallel sample data in the i^{th} first interpolation phase; wherein the serial sample data is obtained by interpolating the multiple-bit transmission data received by the i^{th} output delay circuit over multiple data transmission cycles according to the i^{th} interpolation phase;
the first data rearrangement circuit is used to arrange the positions of the first target parallel sample data formed from the first parallel sample data output by the M first serial and parallel conversion circuits according to the timing. And the adjusted first target parallel sample data is as the parallel bit sample data corresponding to at least one data processing cycle.

4. The device of claim 2, wherein the data oversampling circuit further includes second rearrangement circuits and M second serial and parallel conversion circuits corresponding one-to-one to M output delay circuits. Each second serial and parallel conversion circuits correspond to N second interpolation phases. The data processing clock signal further includes the second data processing sub-clock signal;
the i^{th} second serial and parallel conversion circuit for the j^{th} second interpolation phase, according to the second data processing of the sub-clock signal, performs the j^{th} second interpolation phase processing and the serial and parallel conversion processing of the second preset number of bits on the serial sample data of the corresponding i^{th} output delay circuit in the i^{th} interpolation phase, and outputs the i^{th} first interpolation phase and the second parallel sample data in the j^{th} second interpolation phase. j is each integer value from 1 to N, including both 1 and N, where N is an integer greater than 1;
the second data rearrangement circuit is used to arrange the positions of the N second target parallel sample data formed from the second parallel sample data output by the M second serial and parallel conversion circuits according to the timing. And the adjusted second target parallel sample data is as the parallel bit sample data corresponding to at least one data processing cycle.

5. The device of claim 2, wherein the data oversampling circuit includes third serial and parallel conversion circuits and third rearrangement circuits. The third serial and parallel conversion circuits correspond to the S third interpolation phases. The data processing clock signal further includes the third data processing sub-clock signal;
the third serial and parallel conversion circuit for one-bit transmission data received from each data processing cycle, performs the k^{th} third interpolation phase processing of the transmission data according to the third data processing sub-clock signal. And the interpolated transmission data is as the sample data of the transmission data received over this data processing cycle in the k^{th} third interpolation phase;
the third serial and parallel conversion circuit for the serial and parallel conversion of the third preset number of bits on the serial sample data output in the k^{th} interpolation phase, outputs the third parallel sample data in the k^{th} third interpolation phase; wherein k is each integer value from 1 to S, including both 1 and S, where S is an integer greater than 1;
the third data rearrangement circuit is used to arrange the positions of the third target parallel sample data formed from the third parallel sample data in the S third interpolation phases according to the timing. And the adjusted third target parallel sample data is as the parallel bit sample data corresponding to at least one data processing cycle.

6. The device of claim 1, wherein the data reception circuit includes data buffer circuits and signal compensation circuits;
wherein the data reception circuit receives original transmission data from the data transmitter in accordance with the data reception clock signals, and outputs the transmission data based on the original transmission data, comprising:
wherein the data buffer circuit is used to receive the original transmission data from the data transmitter and output it;
wherein the signal compensation circuit is used to performing signal compensation processing on the original transmission data to obtain the transmission data and output it.

7. The device of any one of claim 2, wherein the data selection circuit includes data edge detection circuits, phase vote circuits, and data output circuits;
wherein the data edge detection circuit for each data processing cycle is used to detect whether or not an edge transition is generated between each two adjacent sample data in the parallel sample data corresponding to the current data processing cycle by means of an exclusive-OR (XOR) gate, and to determine the edge transition position in the current data processing cycle;
wherein the phase vote circuit is used to determine the interpolation phase of the current data processing cycle according to the edge transition position detected by the current data processing cycle;
wherein the data output circuit is used to output the sample data corresponding to the determined interpolation phase.

8. The device of any one of claim 5, wherein the data selection circuit includes data edge detection circuits, phase vote circuits, and data output circuits;
wherein the data edge detection circuit for each data processing cycle is used to detect whether or not an edge transition is generated between each two adjacent sample data in the parallel sample data corresponding to the current data processing cycle by means of an exclusive-OR (XOR) gate, and to determine the edge transition position in the current data processing cycle;
wherein the phase vote circuit is used to determine the interpolation phase of the current data processing cycle according to the edge transition position detected by the current data processing cycle;
wherein the data output circuit is used to output the sample data corresponding to the determined interpolation phase.

9. The device of claim 7, wherein the data selection circuit further includes frequency offset control circuit;
wherein the frequency offset control circuit is used to monitor the edge transition position in each data processing cycle, and whenever the edge transition position of the target data processing cycle is monitored in accordance with the preset conditions, send data output control instructions corresponding to the preset conditions to the data output circuit;
wherein the data output circuit is used to output corresponding to the data output control instructions in the target data processing cycle.

10. The device of claim 9, wherein whenever the edge transition position of the target data processing cycle is monitored in accordance with the preset conditions by the frequency offset control circuit, send data output control instructions corresponding to the preset condition to the data output circuit, including:
wherein whenever the edge transition position of the target data processing cycle is monitored between the sample data of the penultimate and last interpolation phases by the frequency offset control circuit, send the first data output control instructions for outputting 1-bit more sample data to the data output circuit.

11. The device of claim 9, wherein whenever the edge transition position of the target data processing cycle is monitored in accordance with the preset conditions by the frequency offset control circuit, send data output control instructions corresponding to the preset conditions to the data output circuit, including:
wherein whenever the edge transition position of the target receiving cycle is monitored between the sample data of the first and second interpolation phases by the frequency offset control circuit, send the second data output control instructions for outputting 1-bit less sample data to the data output circuit.

12. The device of any one of claim 2, wherein the data recovery circuit further includes temperature sensing control circuit. Each output delay circuit includes multi-stage delay sub-circuit;
for each of the output delay circuits, the temperature sensing control circuit is connected to the multi-stage delay sub-circuit of the output delay circuit through the multiplexer corresponding one-to-one to the multi-stage delay sub-circuit, wherein each selector switch is used to control the corresponding delay sub-circuit of the corresponding output delay circuit;
the temperature sensing control circuit is used to obtain the changes in external temperature and determine the delay sub-circuit to be turned on or off based on the acquired temperature changes, and send an “on” instruction to the delay sub-circuit determined to be turned on, and send an “off” instruction to the delay sub-circuit determined to be turned off.

13. The device of any one of claim 4, wherein the data recovery circuit further includes temperature sensing control circuit. Each output delay circuit includes multi-stage delay sub-circuit;
for each of the output delay circuits, the temperature sensing control circuit is connected to the multi-stage delay sub-circuit of the output delay circuit through the multiplexer corresponding one-to-one to the multi-stage delay sub-circuit, wherein each selector switch is used to control the corresponding delay sub-circuit of the corresponding output delay circuit;
the temperature sensing control circuit is used to obtain the changes in external temperature and determine the delay sub-circuit to be turned on or off based on the acquired temperature changes, and send an “on” instruction to the delay sub-circuit determined to be turned on, and send an “off” instruction to the delay sub-circuit determined to be turned off.

14. A data recovery method that is applied to any one of data recovery circuit described in claim 1, including:
wherein the clock generation circuit outputs data reception clock signals and data processing clock signals;
wherein the data reception circuit receives original transmission data from the data transmitter in accordance with the data reception clock signals, and outputs the transmission data based on the original transmission data;
wherein the data oversampling circuit performs multiple oversampling of at least one bit of transmission data corresponding to at least one data processing cycle according to the data processing clock signal and outputting the parallel sample data corresponding to at least one data processing cycle;
wherein the data selection circuit for each data processing cycle performs transition detection on the corresponding parallel sample data for each data processing cycle and selecting sample data from the corresponding parallel sample data to output based on the transition detection results.

15. A data recovery method that is applied to any one of data recovery circuit described in claim 12, including:
wherein the clock generation circuit outputs data reception clock signals and data processing clock signals;
wherein the data reception circuit receives original transmission data from the data transmitter in accordance with the data reception clock signals, and outputs the transmission data based on the original transmission data;
wherein the data oversampling circuit performs multiple oversampling of at least one bit of transmission data corresponding to at least one data processing cycle according to the data processing clock signal and outputting the parallel sample data corresponding to at least one data processing cycle;
wherein the data selection circuit for each data processing cycle performs transition detection on the corresponding parallel sample data for each data processing cycle and selecting sample data from the corresponding parallel sample data to output based on the transition detection results.
